(19) United States
(12) Patent Application Publication
(10) Pub. No.: US 2026/0017838 A1
(43) Pub. Date: Jan. 15, 2026

(54) AUTOMATIC GENERATION AND PLANTING OF SYNTHETIC DEFECTS OF INTEREST AND GENERATION OF SYNTHETIC FAULT IMAGES OF SEMICONDUCTOR SPECIMENS

(71) Applicant: Applied Materials Israel Ltd., Rehovot (IL)

(72) Inventors: Girish Kumar AJMERA, Bangalore (IN); Yulia BRAND, Hod HaSharon (IL); Saptarshi ROY, Kolkata (IN); Abhishek GOYAL, Ghaziabad (IN)

(21) Appl. No.: 18/769,022

(22) Filed: Jul. 10, 2024

(51) Int. Cl. G06T 11/00; G06T 7/00; G06T 7/50; G06T 7/73

(52) U.S. Cl. CPC G06T 11/00; G06T 7/001; G06T 7/50; G06T 7/74; G06T 2207/20081; G06T 2207/30148

(57) ABSTRACT

The presently disclosed subject matter includes a computer system and a computer-implemented method of automatically generating synthetic defects of interest (DOIs) and planting the DOIs in examination output images, thereby generating synthetic fault images. The proposed technique enables fast, accurate, and efficient generation of a large collection of synthetic fault images (e.g., millions or more), which can be implemented in runtime, as part of the examination process of semiconductor specimens. The synthetic fault images can be generated and used for detecting DOIs on-the-fly during the semiconductor fabrication process.

### TECHNICAL FIELD

The presently disclosed subject matter is related to examination of semiconductor specimens.

### BACKGROUND

A wafer is a thin, usually circular slice of semiconductor material, frequently made of silicon, that serves as a substrate for manufacturing integrated circuits. A semiconductor die is an independent and discrete component of an integrated circuit (e.g., an individual computer processor). Each die contains a specific set of electronic components, all fabricated together on the same wafer. Generally, during the manufacturing process, multiple dies are created on a single wafer, each being a copy of the same integrated circuit, effectively yielding identical copies of the integrated circuit design.

Current demands for high density and performance associated with ultra large-scale integration of fabricated devices require submicron features, increased transistor and circuit speeds, and improved reliability. As semiconductor processes progress, pattern dimensions such as line width, and other types of critical dimensions, are continuously reduced. Such demands require formation of device features with high precision and uniformity, which, in turn, necessitates careful monitoring of the fabrication process, including automated examination of the devices while they are still in the form of semiconductor wafers.

Semiconductor examination is an important part of semiconductor manufacturing process. This includes the inspection of semiconductor wafers for defects of interest (DOIs) to ensure their quality. A DOI may result from various reasons, such as manufacturing process errors, material imperfections, contamination during the fabrication process, malfunction of fabrication equipment, etc. This procedure employs cutting-edge technologies such as optical microscopic imaging, electron microscopy, and automated scanning systems to identify defects like cracks, misalignments, or impurities. These imperfections can significantly affect the yield rate as well as the performance of the final product. Even the smallest fault in a semiconductor can have a substantial impact on the functionality of electronic devices such as computers, smartphones, and other digital equipment, making this inspection process essential for maintaining the reliability and efficiency of electronic components, as well as reducing manufacturing costs and waste, as undetected defects can lead to a significant loss of resources.

### General Description

Run-time examination generally involves generating images of a semiconductor specimen (e.g., wafer or die) and applying various defect detection algorithms on the images for the purpose of detecting defects of interests (DOIs) in the specimen that can affect their functionality and/or performance. A DOI map can be produced to show suspected locations on the specimen having a high probability of being a defect.

Various defect detection algorithms dedicated to classifying defects in inspection output images, and segregating between DOIs and noise, are known. Some algorithms involve machine learning technologies used in the automated examination process, which assist, inter alia, in promoting higher yield. For instance, supervised machine learning can be used for this purpose.

One obstacle in utilizing machine learning (ML) for identifying defects in semiconductor imaging inspection output arises from the limited availability of training data. In environments focused on high-quality manufacturing, actual defects are uncommon, leading to a scant collection of examples of DOIs. This scarcity creates datasets that are heavily skewed towards non-defective examples, which undermines the ML models' capacity to effectively recognize and learn from the rare instances of defects. Moreover, the existing wide range and complexity of potential defects resulting from the diversity in die patterns, adds to the complexity of the training process which requires a large variety of training data. Compounding this issue is the rapid technological progression within the semiconductor industry, which can render any available training data obsolete in a short period, further complicating the process of developing effective ML models for defect detection. Scarcity in DOI examples is also challenging for non-ML algorithms, due to the lack of benchmarks which are needed for verification of the operation in such algorithms.

The presently disclosed subject matter includes a computer system and a computer-implemented method of automatically generating synthetic defects of interest (DOIs) and planting the DOIs in examination output images, thereby generating synthetic fault images. The proposed technique enables fast, accurate, and efficient generation of a large collection of synthetic fault images (e.g., millions or more), which can be implemented in runtime, as part of the examination process of semiconductor specimens. The synthetic fault images can be generated on-the-fly as part of the fabrication process, to enable detecting DOIs in-real time as the semiconductors are being generated.

The synthetic fault images can be used for various purposes, including for example: creating a training dataset of a machine learning model, which can be applied following training on examination (e.g., inspection) output images for discerning between DOIs and noise; serve as benchmark data for defect detection algorithms; and training a human annotator for data classification.

According to a first aspect of the presently disclosed subject matter there is provided a computer-implemented method of generating synthetic fault images of a semiconductor specimen (e.g., wafer or part thereof), wherein a synthetic fault image comprises at least one synthetic defect of interest (DOI), the method comprising:
obtaining examination output images of a semiconductor specimen generated by an examination tool;
generating, from a plurality of examination output images, a respective plurality of synthetic fault images, comprising:
for each examination output image, determining at least one synthetic DOI, comprising:
   determining a DOI planting location in the image;
   determining a planting strength range.
   determining a final DOI shape by fusing a primary DOI shape that is based on optical configuration of the examination tool and secondary DOI shape, selected from a collection of predefined secondary shapes, each comprising a plurality of pixels;
      for each pixel in the final DOI shape, determining a respective DOI pixel strength based on a respective current pixel value and a planting strength selected from within the planting strength range; and
planting the synthetic DOI in the planting location in the image;
thereby generating a collection of synthetic fault images of the semiconductor specimen, wherein different synthetic fault images in the collection comprise different synthetic DOIs, which differentiate in one or more of planting location, DOI pixel strength, and final DOI shape.

In addition to the above features, the method according to this aspect of the presently disclosed subject matter can optionally comprise one or more of features (i) to (ix) below, in any technically possible and technically possible combination or permutation:
(i) The computer-implemented method comprises scanning a semiconductor specimen using an examination tool and generating the examination output images.
(ii) The computer-implemented method comprises, following generation of the plurality of synthetic fault images:
   using the plurality of synthetic fault images for determining whether examination output images comprise any DOIs.
(iii) The computer-implemented method comprises: using the plurality of synthetic fault images for creating a training dataset; training a machine learning model dedicated for detecting defects in examination output images; obtaining at least one additional examination output image comprising a candidate defect; applying the machine learning model to the at least one additional examination output image to thereby obtain machine learning output indicating whether the examination output images comprise one or more DOI.
(iv) The computer-implemented method comprises using, as part of a semiconductor fabrication process, an examination tool for examining one or more fabricated semiconductor specimens and generating the examination output images; and generating the plurality of synthetic fault images by planting synthetic DOIs on-the-fly in the examination output images to thereby enable to use the plurality of synthetic fault images for real-time detection of DOIs in examination output images.
(v) The computer-implemented method comprising augmenting the at least one synthetic DOI comprising: scaling the final DOI shape in one or two dimensions and/or applying rotation of the final DOI shape.
(vi) Wherein fusing the primary DOI shape and secondary DOI shape comprises convolving the primary DOI shape with the secondary DOI shape.
(vii) Wherein each shape in the collection of predefined secondary shapes is represented as a kernel having a certain size with pixels of different colors distributed within the kernel.
(viii) Wherein the primary DOI shape is selected from a database comprising a collection of optional defect shapes which are a product of commonly used optical configurations.
(ix) Wherein the optical configuration of the examination tool includes actual optical configuration and/or presumed optical configuration.

According to a second aspect there is provided a computer system comprising at least one processing circuitry and configured to execute a method of generating synthetic fault images of a semiconductor specimen as disclosed above with respect to the first aspect.

According to a third aspect there is provided a non-transitory computer readable medium comprising instructions that, when executed by a computer, cause the computer to perform a computerized method of generating synthetic fault images of a semiconductor specimen, wherein a synthetic fault image comprises at least one synthetic defect of interest (DOI), the method comprising:
obtaining examination output images of a semiconductor specimen generated by an examination tool;
generating, from a plurality of examination output images, a respective plurality of synthetic fault images, comprising:
for each examination output image, determining at least one synthetic DOI, comprising:
   determining a DOI planting location in the image;
   determining a planting strength range;
   determining a final DOI shape by fusing a primary DOI shape that is based on optical configuration of the examination tool and secondary DOI shape, selected from a collection of predefined secondary shapes, each comprising a plurality of pixels;
      for each pixel in the final DOI shape, determining a respective DOI pixel strength based on a respective current pixel value and a planting strength selected from within the planting strength range; and
planting the synthetic DOI in the planting location in the image;
thereby generating a collection of synthetic fault images of the semiconductor specimen, wherein different synthetic fault images in the collection comprise different synthetic DOIs, which differentiate in one or more of planting location, DOI pixel strength, and final DOI shape.

According to a fourth aspect there is provided a computer system configured to detect defects in examination output images generated by a semiconductor examination tool; the system is configured to execute the method as described above with respect to the first aspect.

According to a fifth aspect there is provided a semiconductor fabrication system comprising a semiconductor examination tool, the system being configured to detect defects in examination output images generated by the semiconductor examination tool.

According to sixth aspect there is provided a semiconductor examination system being configured to receive examination output images of a semiconductor specimen from an examination tool and execute a method of generating synthetic fault images of a semiconductor specimen according to the first aspect above for detecting defects in the examination output images.

Any one of the aspects above can optionally comprise one or more of features (i) to (ix) listed above, mutatis mutandis, in any technically possible combination or permutation.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1 schematically illustrates a general block diagram of a computer system configured to generate synthetic fault images, in accordance with certain examples of the presently disclosed subject matter;

FIG. 2 schematically illustrates a block diagram of a semiconductor examination system that incorporates the system shown in FIG. 1, in accordance with certain examples of the presently disclosed subject matter;

FIG. 3 is a high-level flowchart showing operations carried out as part of a defects of interest (DOI) detection process, in accordance with certain examples of the presently disclosed subject matter;

FIG. 4 is a flowchart showing operations carried out as part of the automatic generation of synthetic fault images, in accordance with certain examples of the presently disclosed subject matter;

FIG. 5 is a flowchart showing operations carried out for determining synthetic DOI shape, in accordance with certain examples of the presently disclosed subject matter;

FIG. 6 is a flowchart showing operations carried out for determining a DOI pixel strength, in accordance with certain examples of the presently disclosed subject matter; and

FIG. 7 shows an example of a collection of spot shapes, in accordance with certain examples of the presently disclosed subject matter.

### DETAILED DESCRIPTION

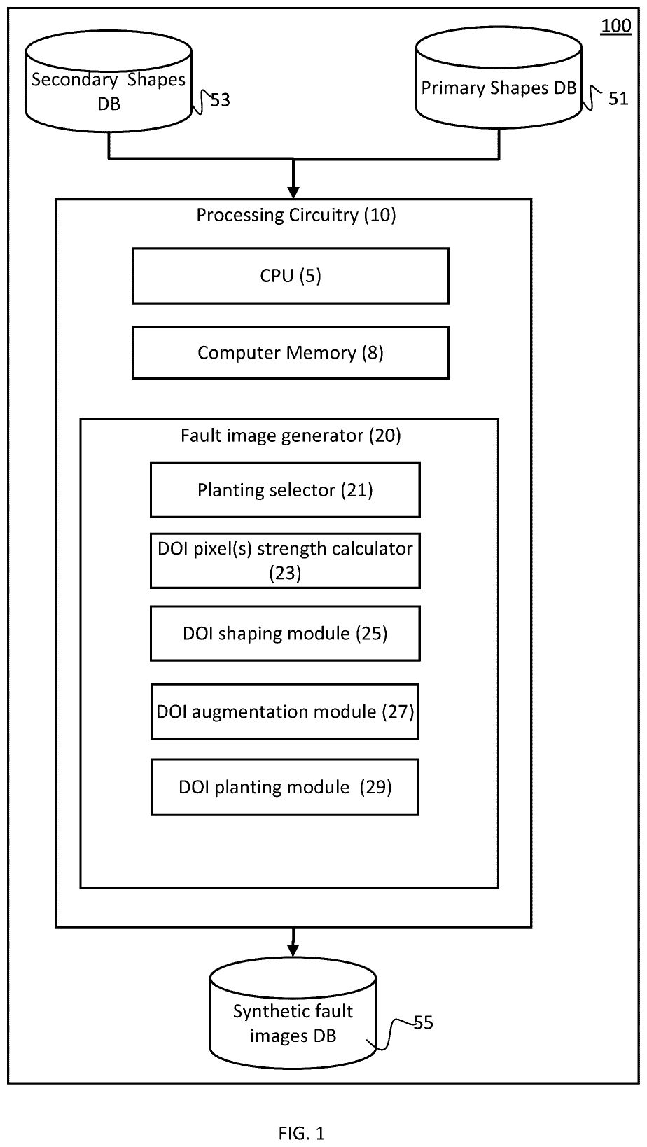

Bearing the above in mind, attention is drawn to FIG. 1, which is a general illustration of a computer system 100 configured with defect planting technology according to examples of the presently disclosed subject matter. A synthetic fault image is generated by artificially planting one or more synthetic DOIs in an image of a semiconductor specimen. A synthetic DOI is a computer-generated defect which is inserted into an examination tool output image, and mimics the characteristics (visual, geometrical, etc.) of a real DOI generated during the semiconductor fabrication process. Examination output images include, for example, images generated by a semiconductor inspection tool (“inspection tool output images”). The term “synthetic fault image” is used herein to refer to an examination tool output image that contains at least one synthetic DOI.

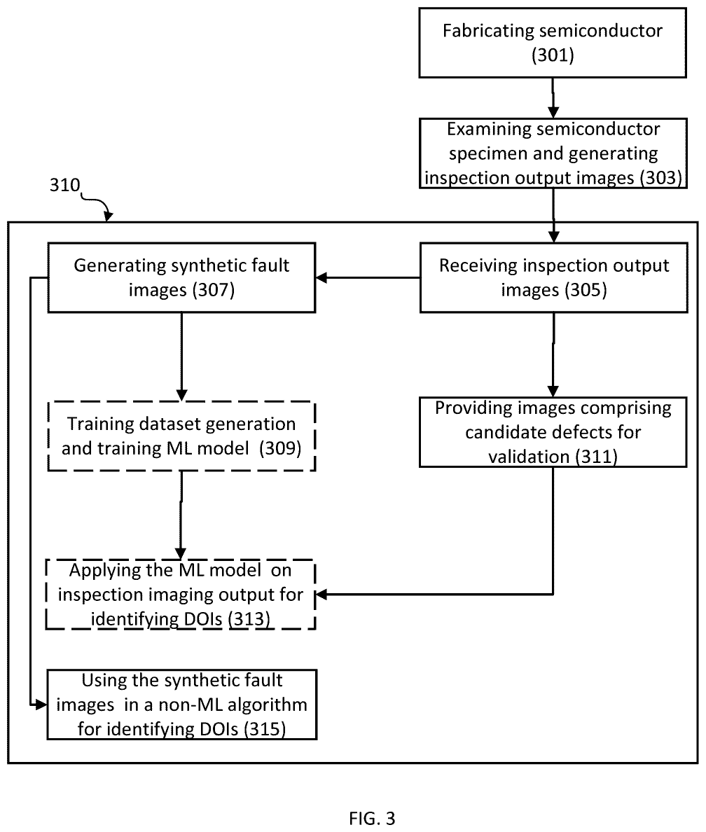

Per the illustrated example, computer system 100 comprises a processing circuitry 10 configured to execute processing necessary for operating the system. This includes processing images of a semiconductor specimen (e.g., a wafer, a die, or parts thereof) generated by an examination tool and generating and planting synthetic defects of interest in the images, thus creating one or more synthetic fault images. Processing circuitry 10 can comprise one or more processors (represented in the figure by CPU 5) and one or more computer memories 8. In some examples, the processing circuitry is configured to execute several functional modules in accordance with computer-readable instructions implemented on a non-transitory computer-readable memory comprised in the processing circuitry. Such functional modules are referred to hereinafter as comprised in the processing circuitry. The functional modules include, for example, fault image generator 20 configured to process examination tool output images and plant synthetic DOIs therein. The specific operations related to each subunit in fault image generator 20 are described below with reference to FIGS. 3 to 5. System 100 also includes one or more computer data storage devices (51, 53 and 55), as further described below.

The generated synthetic fault images can be used, for example, by algorithms dedicated for processing inspection tool output images and identifying DOIs in the images. In one example, a collection of synthetic fault images is generated and used for creating a training dataset for training a machine learning (ML) model dedicated for classification of candidate defects as DOIs or noise. In some examples the ML model is a deep learning model. Computer system 100 can further include or be otherwise operatively connected to a computer storage device dedicated for storing the fault images synthesized by the system (synthetic images database 55).

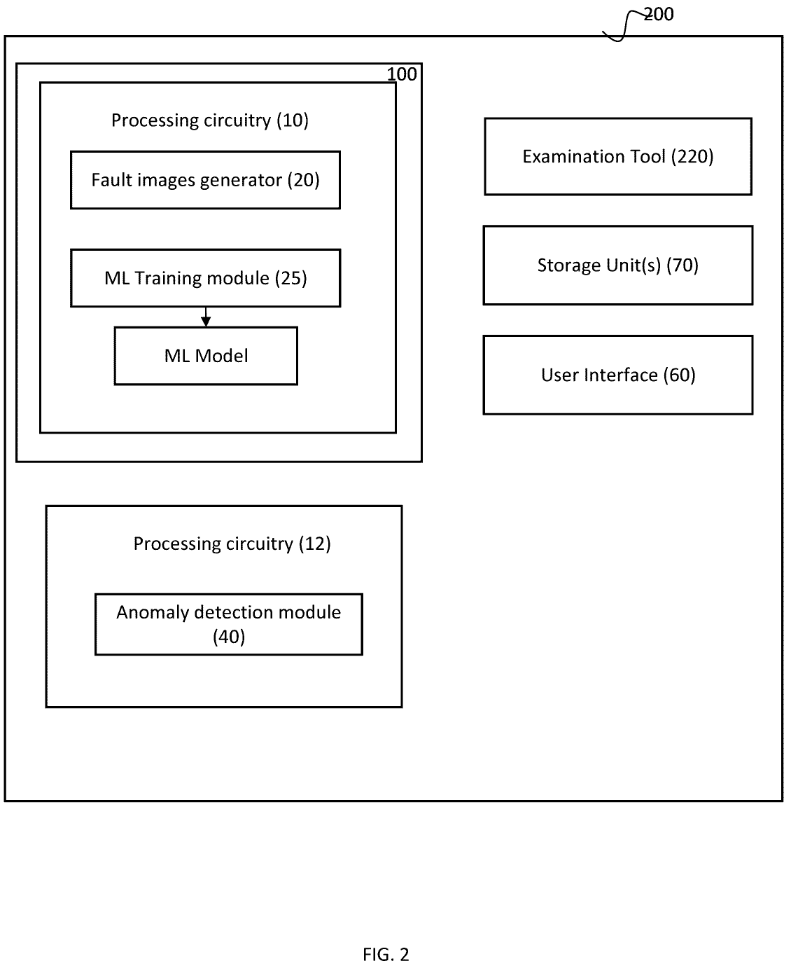

FIG. 2 shows an example where system 100 is integrated in a semiconductor examination system 200. Note that for brevity and clarity not all elements shown in FIG. 1 are also shown in FIG. 2. Examination system 200 can be used for examination of a semiconductor specimen (e.g., a wafer, a die, or parts thereof) as part of the specimen fabrication process. The examination referred to herein can be construed to cover any kind of operations related to defect inspection/detection, defect classification, segmentation, and/or metrology operations, etc., with respect to the specimen. System 200 can comprise one or more examination tools 220 configured to scan a specimen and capture images thereof to be further processed for various examination applications.

The term “examination tool(s)” used herein should be expansively construed to cover any tools that can be used in examination-related processes, including, by way of non-limiting example, scanning (in a single or in multiple scans), imaging, sampling, reviewing, measuring, classifying, and/or other processes provided with regard to the specimen or parts thereof. Without limiting the scope of the disclosure in any way, it should also be noted that the examination tools 220 can be implemented as inspection tools (machines) of various types, such as optical inspection machines and electron beam inspection machines.

The examination tools 220 include, for example, one or more inspection tools. An inspection tool is configured to scan a specimen (e.g., an entire wafer, an entire die, or portions thereof) to capture inspection images (typically, at a relatively high-speed and/or low-resolution) for detection of potential defects (i.e., defect candidates). During inspection, the wafer can move at a step size relative to the detector of the inspection tool (or the wafer and the tool can move in opposite directions relative to each other) during the exposure, and the wafer can be scanned step-by-step along strips (or “swaths”) of the wafer by the inspection tool, where the inspection tool images a part within a strip of the specimen at a time.

By way of example, the inspection tool can be an optical inspection tool. At each step, light can be detected from a rectangular portion of the wafer and such detected light is converted into multiple intensity values at multiple points in the portion, thereby forming an image corresponding to the part/portion of the wafer. For instance, in optical inspection, an array of parallel laser beams can scan the surface of a wafer along the strips. The strips are laid down in parallel rows/columns contiguous to one another, to build up, strip-at-α-time, an image of the surface of the wafer. For instance, the tool can scan a wafer along a strip from up to down, then switch to the next strip and scan it from down to up, and so on and so forth, until the entire wafer is scanned, and inspection images of the wafer are collected. The size of the strip affects the efficiency and resolution of the scanning process. A larger strip can cover more area in less time, but might have lower resolution, while a smaller strip can offer higher resolution imaging, but takes more time to cover the same area. Another example of an inspection tool often used for inspection of semiconductors as part of a semiconductor fabrication process is a Scanning Electron Microscope (SEM).

In some cases, the examination tools 120 include a review tool configured to provide a detailed examination of specific areas on a semiconductor wafer, particularly those areas where defects or anomalies have been identified by an inspection tool. It allows for close-up, in-depth analysis of these defects. A review tool is usually configured to inspect fragments of a specimen, one at a time (typically, at a relatively low-speed and/or high-resolution) and generate images of the reviewed area. By way of example, the review tool can be an electron beam tool, such as, e.g., scanning electron microscopy (SEM), etc. An SEM is a type of electron microscope that produces images of a specimen by scanning the specimen with a focused beam of electrons. The electrons interact with atoms in the specimen, producing various signals that contain information on the surface topography and/or composition of the specimen.

The inspection tool and review tool can be different tools located at the same or at different locations, or a single tool operated in two different modes. In some cases, the same examination tool can provide low-resolution image data and high-resolution image data. The resulting image data (low-resolution image data and/or high-resolution image data) can be transmitted—directly or via one or more intermediate systems—to system 100. The present disclosure is not limited to any specific type of examination tools and/or the resolution of image data resulting from the examination tools. In some cases, at least one examination tool 220 with metrology capabilities and capability to capture images and perform metrology operations on the captured images, is used. Such an examination tool is also referred to as a metrology tool.

In some examples, examination system 200 is configured with automatic defect examination capability in a semiconductor specimen. As part of the semiconductor fabrication process, inspection tool output images are processed by system 200 in runtime for classifying candidate defects identified in the images and detecting DOIs. To this end system 200 can further include anomaly detection module 40, which is shown by way of example to be implemented in a dedicated processing circuitry 12 but can be otherwise implemented as part of system 100.

Anomaly detection module 40 is configured to implement a DOI detection algorithm. According to some examples, the DOI detection algorithm is implemented as a machine learning (ML) model trained on a training dataset comprising inspection tool output images, including fault images and images without defects. The trained ML model is applied on test data comprising one or more inspection tool output images generated by an inspection tool.

According to some examples, system 100 and/or 200 can comprise one or more computer data-storage units 70. The storage unit 70 can be configured to store any data necessary for the operations of system 200, e.g., computer software which is loaded to memory during execution of any one of the modules described above, intermediate processing results generated by system 100, synthetic fault images, the inspection output images received from the examination tool, the training dataset, the trained ML model, and/or the outputs of the ML model, etc. In some examples, data-storage unit 70 is used for implementing one or more of databases 53, 51, and 55.

According to some examples, system 200 and/or 100 comprises a user interface 60, to enable user interaction with system 200 and/or 100. The user interface can include a display device, user interaction devices (e.g., computer mouse and keyboard), and a graphical user interface (GUI) configured to enable, inter alia, user-specified inputs related to system 200 and/or 100. For instance, the user may be provided, through the GUI, with options of defining certain operations and/or parameters. The user may also view on the display the processing results or intermediate processing results, such as, e.g., synthetic DOIs, the synthetic fault images, etc.

Turning to FIG. 3, it shows a high-level flow chart of operations carried out as part of a runtime anomaly detection process, in accordance with some examples of the presently disclosed subject matter. For better clarity, and by way of non limiting example only, operations in FIGS. 3 to 5 are described with reference to the system components shown in FIGS. 1 and 2.

FIG. 3 demonstrates a process related to a non-limiting example of a use-case, where the generation of synthetic DOIs and synthetic fault images is implemented as part of the semiconductor fabrication process. During semiconductor fabrication (301) the fabricated specimen is examined using an examination tool 220 (303). As part of this process, inspection tool output images of semiconductor specimens are generated. As explained above, inspection of a wafer may involve performing multiple passes over the wafer, where a respective strip is scanned during each pass. Depending on the size of the strip and the dies, a single strip might cover multiple dies or only a part of a die. Thus, the imaging output corresponding to each strip normally comprises information from multiple dies that are located along the strip scanning line. In this context, each strip is divided into a plurality of sections, known as ‘tiles’ or ‘patches,’ with each section representing a detailed portion of the strip, including parts of different dies scanned along the strip. In some examples, each inspection output image represents the information from a single patch.

Some of the inspection tool output images comprise candidate defects that were identified by the inspection tool (referred to herein also as “defect inspection images”). Other inspection tool output images are clear of defects. In some examples, identification of inspection images that comprise candidate defects involves comparison between patches from different dies, or between a patch and a reference. In some examples, multiple patches are compared, where one patch is designated as current, and the others are designated as reference patches, where reference could be from a different die or from the same die or a die simulation. In one example, three patches are used, including a current patch, reference 1 and reference 2. A candidate defect is identified in the current patch if it exhibits a pattern or some other feature which is different to the pattern or feature at the same location in reference 1 and reference 2.

The defect inspection images are provided to computer system 100, where they are processed to determine whether the candidate defects are DOIs or noise (blocks 305, 311 and 313; e.g., by anomaly detection module 40). Synthetic fault images, which facilitate the identification of DOIs, are used by system 100 for this purpose.

When a new type of semiconductor specimen (characterized for example by a particular material composition, architecture, and geometry) is initially fabricated, synthetic fault images can be synthesized by computer system 100 to be used for DOI detection. To this end, inspection tool output images are provided to processing circuitry 10, which is configured to generate and plant in the images, synthetic defects, thus creating a pool of synthetic fault images (blocks 305 and 307; e.g., by fault images generator 20). Once the synthetic fault images are available, they are used for processing defect inspection images received from examination tool 220 and identifying DOIs (e.g., through thread 305, 311, and 313).

In some examples, where an ML model is used for identification of DOIs, the synthetic fault images can be used for creating a training dataset for training the model (309; e.g., by training module 30 in processing circuitry 10). In the context of semiconductor examination, synthetic fault images and defect-free images are combined to create a training dataset, which is then used during the training phase for training.

Various image processing techniques can be applied on the images (including synthetic fault images) for extracting feature values corresponding to different features. The features pertain for example to color, shape, size, orientation, location in image, etc. characterizing defects in the images (including synthetic DOIs planted in the synthetic fault images). These techniques include, for example, edge detection, color segmentation, and object detection. Notably, some features may be available from the synthetic DOIs generation process. Features extraction can be executed, for example, by a dedicated module (not shown). A record comprising the respective features can be created for each defect. In some examples, a table comprising multiple records, each record corresponding to a respective synthetic DOI and its respective features, is created and used during training of the ML model.

For a supervised ML model, data labeling is performed, where each record corresponding to a respective defect is annotated according to its respective class, including at least two classes, namely true defect of interest (DOI) and noise. In one example, data labeling incudes manually adding appropriate annotation to the data corresponding to each defect using for example, an appropriate software tool. In other examples, automatic computer-implemented labeling is applied.

Notably, using features extraction for an ML model is only one non-limiting example of a DOI detection technique. In other examples, the entire images are used as input to a deep learning model without the need for feature extraction.

In case an ML model is being implemented, once the ML model is ready for execution, it is applied to defect inspection images received from the examination tool for classifying candidate defects in the images (313). Notably, in case a different, non-ML algorithm is used for classifying inspection tool output images, the training phase (309) may not be executed. In such scenarios, the synthetic fault images can be utilized differently by the algorithm (block 315). For instance, these images could serve as benchmark data for characterizing defects, providing a standard or reference against which defect inspection images are compared and analyzed. Additionally, the synthetic fault images can be used for optimizing parameters for a non-ML defect detection algorithm.

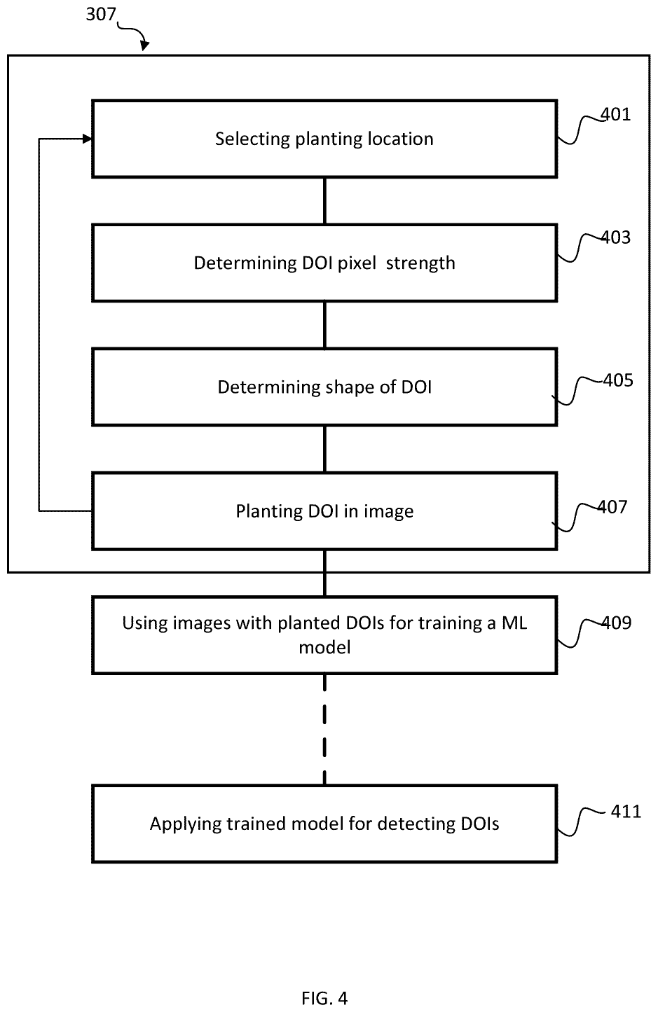

FIG. 4 is a flowchart of operations carried as part of synthetic fault images generation, according to examples of the presently disclosed subject matter. These operations are executed automatically by the system (e.g., by fault image generator 20) to provide automatic synthesis of fault images.

During the process of generating synthetic fault images, an inspection tool output image is processed and altered so it includes at least one synthetic DOI. The image can be an image of a semiconductor specimen or a part thereof.

A planting location within the image, where the synthetic DOI is to be planted, is determined by the system (401; e.g., by planting selector 21). As part of this, certain areas within the image are identified and excluded from the planting process. Areas excluded from planting are areas in semiconductor specimens (e.g., patches) where real DOIs are unlikely to be detected. Examples of excluded areas include:
Specimen margin—areas located at the margin of the specimen in the image near the edges. These areas are excluded as they may not allow to plant a sufficiently large synthetic DOI.
Customized areas—areas where the existence of DOIs is not of interest, for example areas which do not affect the functioning of the semiconductor. These areas include, for example, testing regions for performing various tests on the die where the existence a DOI is not important, non-functional areas of die, areas designated for drilling, etc.
Optically insignificant areas—in optically insignificant areas a DOI is unlikely to be detected since it will not be discernible from the background. These areas depend on the specific geometry and the specific optical configuration applied during scanning by the examination tool. Therefore, the images are processed, and the optically insignificant areas are identified according to their respective pixel values and excluded from the planting locations. Examples of optically insignificant areas include areas with grey level (GL) below a certain minimal GL value, above a certain maximal GL value, and areas having a particular pattern.

With respect to optical insignificance, applying a binary threshold, where only pixels with values below a minimum pixel value threshold and/or above a maximum pixel value threshold are excluded from planting, would create a technical problem, due to variations in the pixel values in different images of different semiconductor specimens. Since this is an optical phenomenon, which may vary from one image to another, some pixels located in optical insignificance areas may be assigned with pixel values below the maximal pixel threshold or above the minimal pixel threshold, and, accordingly, may be undesirably selected as a planting location.

To avoid this, a distance map indicating the Euclidean distance of each pixel from optical insignificance threshold values is created. The distance map indicates optical insignificance areas comprising, pixels with values above a maximal optical insignificance threshold, pixels below the minimal saturation threshold, and transition areas comprising pixels with values which are below the maximal optical insignificance threshold, and above a minimal optical insignificance threshold which are located within a predefined Euclidean distance from optically insignificant pixels. Transition areas are excluded from planting.

Once the areas excluded from planting are identified and marked, a planting area for one or more defects is selected. This can be done based on various logics, including, for example, by randomly selecting a planting area. Another example is by template matching (identifying a specific template of patterns or specific GL values, and planting in pixels that comply with these parameters). Additionally, a planting location can be determined based on custom information such as design data or hotspots in the semiconductor design indicating areas with a high probability of real defect occurrence. A selected planting area corresponds to one or more pixels in the image which will be modified to represent a synthetic DOI.

The intensity values (“strength”) of the pixels in the DOIs are determined (403; e.g., by DOI pixel value calculator 23). To this end a minimal strength value and maximal strength value are determined. The appropriate minimal and maximal strength values for synthetic DOIs are established by factoring in the image's noise values, to ensure they surpass the strength of noisy pixels.

A maximal strength can be determined according to the optical configuration which is used during scanning. If scanning is in the dark field or grey field, the output images are generally characterized by darker background. Accordingly, the maximal strength can be relatively high (e.g., 255 in an 8-bit image). If scanning is in the bright field, the output images are generally characterized by lighter background. Accordingly, the maximal strength is determined according to the typical grey level in the image. In such cases, system 100 is configured to calculate (e.g., by DOI pixel value calculator 23) a typical grey level value in the image, and determine the maximum strength according to the calculated value. The typical grey level value can be calculated, for example, based on the observed values of the pixels in the image, e.g., determining the average intensity of the pixels across the entire image. Alternatively, this value can be received as user input.

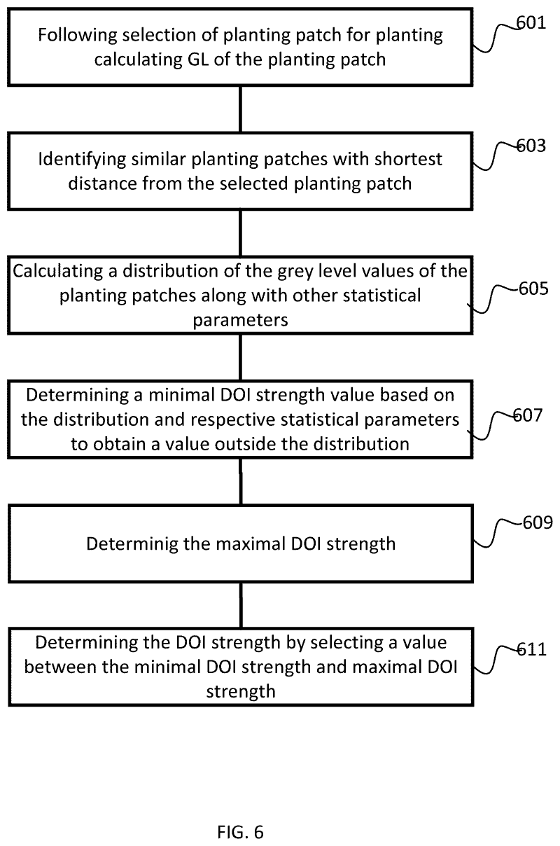

A minimal strength value can be determined based on a noise value (N) multiplied by a noise factor (N×NF), e.g., Noise Factor=2. Various methods can be applied for calculating the noise (N) value in each image. One example of a method of calculating noise value and determining a DOI strength for pixels of a planted DOI is disclosed herein with reference to FIG. 6. The description returns to FIG. 4 after completing the discussion of FIG. 6.

A DOI may include a plurality of pixels (“compound DOI”) or, in some cases, a single pixel, where the term “planting patch” may be used herein to refer to a location in the image selected for planting, including both singular DOIs and compound DOIs. Notably, the noise value depends on the specific pixel selected for planting and the planting patch in which it is being planted. Accordingly, different pixels in the same image may have different respective noise values.

Assuming it is desired to plant a defect in a certain planting patch, the following operations are executed:

The GL value of the planting patch is calculated (block 601). If the planting patch is a single pixel DOI, the DOI GL equals the GL value of the pixel. Otherwise, this can be calculated, for example, as an average or weighted average of the pixel values located in the planting patch selected for planting, or according to the value of the central pixel in the planting patch.

Next, similar planting patches are identified (block 603). If reference images (other images of the same semiconductor specimen) are available, similar patches can be found in the reference images. Otherwise, similar patches can be found in the same image. Similarity between planting patches can be determined based on methods such as mean square error (MSE) applied on the image, Euclidean distance, correlation in Structural Similarity Index Measure (SSIM), etc. The distance (similarity between planting patches) can be defined according to some predefined threshold. For example, in case Euclidean distance is used, the threshold can be defined as below 10%, and in case correlation is in SSIM, the threshold can be defined as correlation above 0.9.

Once a group of closest similar planting patches is determined, a collective distribution of the grey level values of all planting patches is calculated, along with other statistical attributes such as mean (μ) grey level value and standard deviation (STD; block 605).

The grey level value of the planting patch selected for planting serves as a working grey level (WGL), located within the distribution. A minimal strength value (to be applied on the WGL to obtain the DOI value) of the DOI is determined based on the distribution. A grey level assigned to a DOI in the planting patch should be outside the distribution boundaries, otherwise it is likely to be undetectable, given the grey level values of similar planting patches. Bearing this in mind, a minimal DOI strength value is calculated based on the distribution and the respective statistical attributes that are located outside the distribution (block 607). For example, a minimal DOI strength can be calculated by:

$$Min Strength = N \times NF$$

$$N = μ + Fx \times STD$$

where Fx is a predefined factor and y and STD are determined based on the distribution of pixels of the planting patch and its similar patches; μ generally corresponds to WGL. In case of non-Gaussian distribution, a Gaussian Mixture Model (GMM) can be used.

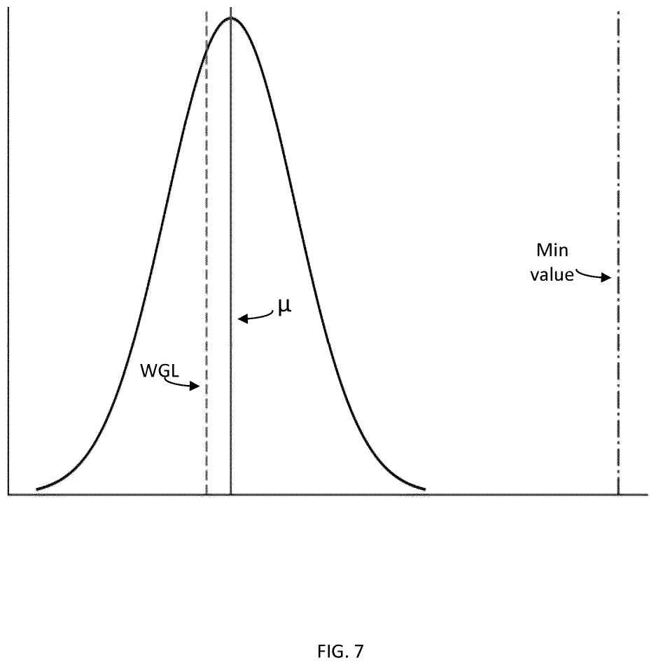

FIG. 7 is a graph exemplifying the calculation of pixel strength, where the distribution of pixel values in planting patches is shown along with the WGL and the mean. The minimal strength pixel value is located outside of the distribution, indicated by the line on the far right.

The calculation described above is for a selected planting patch for planting that comprises a matrix of M×M pixels. In case the planting patch selected for planting in a singular pixel, a similarity threshold for identifying similar pixels in the image is based on a range of pixel values close to the value of the pixel selected for planting. For example, assuming the pixel selected for planting has a grey level value of 100, similar pixel values can range between 98 to 102. Pixels that fall within the range are identified in the current image.

As explained above with respect to a planting patch comprising a pixel matrix, a minimal DOI strength value is calculated based on the collective distribution and the respective statistical attributes that are located outside the distribution (block 607). For example, a minimal DOI strength can be calculated by, μ+Fx×STD, where Fx is a predefined factor.

The maximal DOI strength value is determined as well (block 609). In some examples, maximal DOI strength value is left open, i.e., with no limit. In other examples, it is determined according to the optical configuration of the image.

Once the minimum (Min) and maximum (Max) DOI strength values are determined, the actual planting strength value (Strength value) is determined by selecting a value within this specified Min-Max range (block 611). This selection process can be effectively achieved by applying a desired distribution across the range of DOI strength values. A random selection can then be applied to this distribution, biasing the choice of the strength value within the Min-Max range according to the distribution's characteristics. The method allows for the use of various selection distributions, including, for example, a uniform distribution, a custom distribution, a distribution skewed toward the maximum DOI strength value, or a distribution skewed toward the minimum DOI strength value, depending on the specific requirements of the use case.

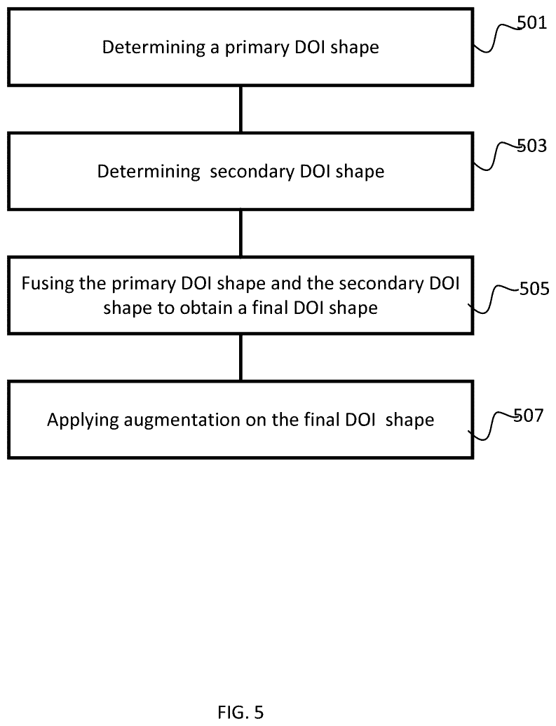

Once the strength value is available, it is used to calculate the pixel values of the DOIs, where the pixel values are determined based on the strength value and the current pixel values of the pixels in the DOI. A process of determining the shape of the DOI is described with reference to FIG. 5 below. In some examples, a DOI is defined as a 2D area in the image having a particular shape with normalized pixel values between 0 and 1 (referred to as a “stamp”), where the values define variations in the defect of interest. Normalization can be done by dividing all values by the max value in the shape. the Notably, the stamp can be either greater or smaller than the respective planting patch. Higher normalized values represent areas where the defect is more pronounced or severe. In some examples, the stamp can include the entire image, where areas that are not part of the defect are assigned a value of zero. In other examples, the stamp may include only the area of the DOI and can be localized in the original images based on the corresponding image coordinates.

The pixel value of each pixel in a DOI is calculated by multiplying the normalized value of each pixel in the stamp by the strength value and addition of the product to the current value of the pixel.

$${DOI}_{i , j} = ( {S}_{i , j} \times Strength value ) + {C}_{i , j}$$

Where:
DOI_{i,j} is the calculated value of an (i,j) pixel in the DOI;
S_{i,j} is the normalized value of an (i,j) pixel in the stamp; and
C_{i,j} is the current value of an (i,j) pixel in the DOI.

To avoid a DOI pixel value which is out of bounds, a cutoff operation is applied (e.g., by DOI pixel value calculator 23). If the calculated DOI pixel value is lower than some low threshold value (e.g., 5), the DOI pixel value is amended to the low threshold value. Likewise, if the calculated DOI pixel value is lower than a high threshold value (e.g., 255), the DOI pixel value is amended to the high threshold value. The cutoff values depend on bit resolution of the images. If images are stored in 8-bit or 16-bit, values are limited by 8 bit or 16 bit.

Reverting to FIG. 4, for each DOI a respective shape is determined (405; e.g., by DOI shaping module 25). FIG. 5 is a flowchart of operations carried out as part of the DOI shape determination process, according to examples of the presently disclosed subject matter.

A primary DOI shape is determined (501; DOI shaping module 25). The primary DOI shape represents the optical configuration (e.g., spot optical configuration) used by the inspection tool during scanning. In the context of SEM this refers to the configuration of electromagnetic lenses and apertures used to generate, focus, and scan the electron beam over the sample. Parameters that define the optical configuration include, for example, spot shape, polarization, gain, collection aperture, light intensity, etc.

Assuming the optical configuration used during scanning is known (“actual optical configuration”) this can be used this to determine the primary defect shape, for example from a database that associates different optical configurations with respective primary shapes. Given the optical configuration of the inspection tool, as defined by a group of parameters, a respective primary shape can be retrieved from the database. If the optical configuration used during scanning is unknown, the primary defect shape can be selected from a database of primary defect shapes (“presumed optical configuration”), which includes a collection of possible defect shapes (e.g., stored for example in database 51) which are the product of various commonly used optical configurations.

Since, in some examples, defect shapes are characterized by a univariate Gaussian or bivariate Gaussian geometry, the defect shapes database may include a variety of different univariate Gaussian or bivariate Gaussian defect shapes. The shapes in the database differ in their various characteristics, including, for example, mean vector, covariance matrix, and corresponding shape and orientation (being more elliptical or more circular), etc.

In some examples, selection of a primary defect shape from the database is random or partially random (e.g., where the primary defect shape is known to be either univariate Gaussian or bivariate Gaussian, but the specific univariate Gaussian or bivariate Gaussian shape is unknown). The database can include univariate Gaussian or bivariate Gaussian primary shapes and/or primary shapes generated based on optical configurations.

For example, in case the inspection output images are used for creating a training set for training a ML model, and are obtained from more than one inspection tool to create a universal DOI detection model applicable to the output of various inspection tools, more than one primary defect shape is used to represent DOIs created by the different types of tools. In such case, a combination of univariate and bivariate primary defect shapes can be selected and used. Also, different primary shapes, each characterized based on optical configuration of a different optical inspection tool/modes, can be used as well.

If on the other hand, only one type of inspection tool is used during examination, and the ML model is intended to be applied on examination output images generated by that tool alone, one primary defect shape of the specific inspection tool may be used.

A secondary DOI shape is determined (503). According to some examples, a secondary defect shape is selected from a database comprising a variety of different possible secondary defect shapes (e.g., database 53).

The secondary defect shapes can be represented as a collection of patterns or kernels. Each kernel comprises a matrix having a certain size (i.e., a two-dimensional array or grid that organizes the location of each pixel in the kernel), where pixels of different values are distributed over the matrix. Different kernels represent different types of defects, such as bridges or scratches, and are therefore constructed according to the typical appearance of these defects in an image, e.g., having a unique pixel distribution and size.

The database may comprise different subgroups of kernels, each subgroup comprising kernels of a different type. For example, a first subgroup can include a collection of kernels representing defect shapes determined based on actual defects found in examination output images. The matrixes in the first subgroup can be of various sizes. A second subgroup can include a collection of computer-generated kernels. For example, kernels can be randomly generated by creating an M×M pixel matrix, where between one to a certain maximal percentage (e.g., 1 to 50) of the pixels are assigned as defects (0> and ≤1), and the rest are assigned with a value that represents the background (e.g., 0). In some examples, pixels are assigned according to some expected pattern typically seen in a certain type of defect (e.g., diagonal lines at different angles to represent a scratch). This type of defect includes point defects, which correspond to a defect comprising a very small number of pixels, e.g., two or three. A third subgroup of defects can include large defects encompassing a large area of the specimen (e.g., a planting patch larger than the defects in the other subgroups).

Secondary defects shapes can be randomly selected from the defects database. In certain examples, where multiple defects are selected (e.g., for creating a training dataset), the selection process is carried out, such that the number of defects chosen from each subgroup reflects the observed distribution of defects in real-life scenarios.

Once a primary defect shape and a secondary defect shape have been selected, the two shapes are fused together, and a final defect shape is generated (505; e.g., by DOI shaping module 25).

Fusion emulates the process that normally occurs when a defect is scanned during examination by the inspection tool. Given the primary defect shape and the secondary defect shape, the final defect shape is the expected appearance of the shape in an examination output image.

Fusion can be implemented in various ways. One example is by convolving the primary defect shape with the secondary defect shape, where the secondary defect kernel is used as a convolutional kernel. Another example is by a ML model which is trained to receive, as input, the primary defect shape and the secondary defect shape, and provide, as output, a final defect shape.

Augmentation may be applied on the final DOI shape to further increase diversity (505; e.g., by DOI augmentation module 29). While repeatedly fusing (e.g., convolving) between a certain primary DOI shape and a certain secondary DOI shape would result in the same final DOI shape, in real-world scenarios this may not be so due to differences in additional parameters, such as the background characteristics or scanning speed. Augmentation may be critical in case a training dataset of synthetic fault images is being created to avoid overfitting of the ML model. Augmentation includes, for example, scaling the final DOI shape in one or two dimensions (e.g., increasing the size of the shape) and/or applying rotation on the final DOI shape. As explained above, the final DOIs can be represented as 2D areas or stamps assigned with normalized values ranging between zero and 1.

The above process is repeated during the generation of each synthetic fault image at least once for creating at least one synthetic DOI. Once the planting location, strength, and shape of the synthetic DOI have been determined, a respective synthetic DOI is planted at the selected planting location within the processed image, thus creating a respective synthetic fault image (409; e.g., by DOI planting module 31).

The process described with reference to block 307 in FIG. 4 can be repeated multiple times with different inspection output images to create multiple synthetic fault images. As explained above, different operations in the process include a randomization component to ensure that different synthetic fault images include different synthetic DOIs. The synthetic DOIs may differ, for example, in one or more of their planting location, their shape, and their pixel values. Thus, this process enables to quickly generate, in real-time, a highly diversified collection of synthetic fault images which are generated using images of a specific semiconductor product which is characterized by a specific semiconductor topology.

Once ready, the synthetic fault images can be used for detecting DOIs in defect output images (409). In case a machine learning model is used, the synthetic fault images can be used for training the model. Following training, the trained model can be applied on the inspection tool output images as part of the verification process, to discern between DOIs and noise.

While certain examples of the present disclosure refer to a processing circuitry being configured to perform the above recited operations, the functionalities/operations of the aforementioned functional modules can be performed by the one or more processors in the processing circuitry in various ways. By way of example, the operations of each module can be performed by a specific processor, or by a combination of processors. The operations of the various functional modules, such as processing the examination/inspection image, and performing defect examination, etc., can thus be performed by respective processors (or processor combinations), while, optionally, these operations may be performed by the same processor. The present disclosure should not be limited to being construed as one single processor always performing all the operations.

Those versed in the art will readily appreciate that the teachings of the presently disclosed subject matter are not bound by the system illustrated in FIGS. 1 and 2. Each system component and module in FIGS. 1 and 2 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIGS. 1 and 2.

Each component in FIGS. 1 and 2 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

The system illustrated in FIGS. 1 and 2 can be implemented in a distributed computing environment, in which one or more of the aforementioned components and functional modules shown in FIGS. 1 and 2 can be distributed over several local and/or remote devices. By way of example, the examination tool 220 and the system 100 can be located at the same entity (in some cases hosted by the same device), or distributed over different entities, each located at a different location.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages and drive signals, and can be wired and/or wireless, as appropriate.

It should be further noted that in some embodiments at least some of examination tools 220 and/or storage unit 70 can be external to system 200 and operate in data communication with systems 200 over a suitable communication link. System 200 can be implemented as stand-alone computer(s) to be used in conjunction with the examination tools, and/or with the additional examination modules, as described above. Alternatively, the respective functions of system 200 can, at least partly, be integrated with one or more examination tools 200, thereby facilitating and enhancing the functionalities of the examination tools 200 in examination-related processes.

Unless specifically stated otherwise, as apparent from the above discussions, it is appreciated that, throughout the specification, discussions utilizing terms such as “obtaining”, “generating”, “determining”, “selecting”, “convolving”, “fusing”, “augmenting”, “planting” or the like, include an action and/or processes of a computer that manipulate and/or transform data into other data, said data represented as physical quantities, e.g. such as electronic quantities, and/or said data representing the physical objects.

The terms “computer”, “computer system”, “computer device”, “computerized device” or the like used herein, should be expansively construed to include any kind of hardware-based electronic device with one or more data processing circuitries. Each processing circuitry can comprise, for example, one or more processors operatively connected to computer memory, capable of executing stored instructions to perform the operations described herein.

The one or more processors referred to herein can represent one or more general-purpose processing devices, such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices, such as an application specific integrated circuit (ASIC), a field programmable gate array (FPGA), a digital signal processor (DSP), a graphics processing unit (GPU), a network processor, or the like. The one or more processors are configured to execute instructions for performing the operations and steps discussed herein.

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately, or in any suitable sub-combination.

In embodiments of the presently disclosed subject matter, fewer, more and/or different stages than those shown in FIGS. 4 to 6 may be executed. In embodiments of the presently disclosed subject matter, one or more stages illustrated in the figures may be executed in a different order, and/or one or more groups of stages may be executed simultaneously.

It will also be understood that the system according to the presently disclosed subject matter may be a suitably programmed computer. Likewise, the presently disclosed subject matter contemplates a computer program being readable by a computer for executing the method of the presently disclosed subject matter. The presently disclosed subject matter further contemplates a machine-readable (e.g., non-transitory) memory tangibly embodying a program of instructions executable by the machine for executing the method of the presently disclosed subject matter.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

1. A computer-implemented method of generating synthetic fault images of a semiconductor specimen, wherein a synthetic fault image comprises at least one synthetic defect of interest (DOI), the method comprising:
obtaining examination output images of a semiconductor specimen generated by an examination tool;
generating, from a plurality of examination output images, a respective plurality of synthetic fault images, comprising:
for each examination output image, determining at least one synthetic DOI, comprising:
determining a DOI planting location in the image;
determining a planting strength range;
determining a final DOI shape by fusing a primary DOI shape that is based on optical configuration of the examination tool and secondary DOI shape, selected from a collection of predefined secondary shapes, each comprising a plurality of pixels;
for each pixel in the final DOI shape, determining a respective DOI pixel strength based on a respective current pixel value and a planting strength selected from within the planting strength range; and
planting the synthetic DOI in the planting location in the image;
thereby generating a collection of synthetic fault images of the semiconductor specimen, wherein different synthetic fault images in the collection comprise different synthetic DOIs, which differentiate in one or more of planting location, DOI pixel strength, and final DOI shape.

2. The computer-implemented method of claim 1 comprising:
scanning a semiconductor specimen using an examination tool and generating the examination output images.

3. The computer-implemented method of claim 2 comprising:
following generation of the plurality of synthetic fault images:
using the plurality of synthetic fault images for determining whether examination output images comprise any DOIs.

4. The computer-implemented method of claim 3, comprising:
using the plurality of synthetic fault images for creating a training dataset;
training a machine learning model dedicated for detecting defects in examination output images;
obtaining at least one additional examination output image comprising a candidate defect;
applying the machine learning model to the at least one additional examination output image to thereby obtain machine learning output indicating whether the examination output images comprises one or more DOIs.

5. The computer-implemented method of claim 3 comprising: using as part of a semiconductor fabrication process, an examination tool for examining one or more fabricated semiconductor specimens and generating the examination output images; and
generating the plurality of synthetic fault images by planting synthetic DOIs on-the-fly in the examination output images to thereby enable to use the plurality of synthetic fault images for real-time detection of DOIs in examination output images.

6. The computer-implemented method of claim 1 comprising augmenting the at least one synthetic DOI comprising: scaling the final DOI shape in one or two dimensions and/or applying rotation of the final DOI shape.

7. The computer-implemented method of claim 1, wherein fusing the primary DOI shape and secondary DOI shape comprises convolving the primary DOI shape with the secondary DOI shape.

8. The computer-implemented method of claim 1, wherein each shape in the collection of predefined secondary shapes is represented as a kernel having a certain size with pixels of different colors distributed within the kernel.

9. The computer-implemented method of claim 1, wherein the primary DOI shape is selected from a database comprising a collection of optional defect shapes which are a product of commonly used optical configurations.

10. The computer-implemented method of claim 1, wherein the optical configuration of the examination tool includes actual optical configuration and/or presumed optical configuration.

11. A computer system configured and operable to automatically generate synthetic fault images of a semiconductor specimen, wherein a synthetic fault image comprises at least one synthetic defect of interest (DOI); the computer system comprising at least one processing circuitry configured to:
obtain examination output images of a semiconductor specimen generated by an examination tool;
generate, from a plurality of examination output images, a respective plurality of synthetic fault images, comprising:
for each examination output image determining at least one synthetic DOI, comprising:
determining a DOI planting location in the image;
determining a planting strength range;
determining a final DOI shape by fusing a primary DOI shape that is based on optical configuration of the examination tool and secondary DOI shape, selected from a collection of predefined secondary shapes, each comprising a plurality of pixels;
for each pixel in the final DOI shape, determining a respective DOI pixel strength based on a respective current pixel value and a planting strength selected from within the planting strength range; and
planting the synthetic DOI in the planting location in the image;
thereby generating a collection of synthetic fault images of the semiconductor specimen, wherein different synthetic fault images in the collection comprise different synthetic DOIs, which differentiate in one or more of, planting location, DOI pixel strength, and final DOI shape.

12. The computer system of claim 11 comprising or being otherwise operatively connected to the examination tool, which is configured to scan a semiconductor specimen using an examination tool and generate the examination output images.

13. The computer system of claim 12, wherein the at least one processing circuitry is configured, following generation of the plurality of synthetic fault images, to use the plurality of synthetic fault images for determining whether examination output images comprise any DOIs.

14. The computer system of claim 13, wherein the at least one processing circuitry is configured to:
use the plurality of synthetic fault images for creating a training dataset;
train a machine learning model dedicated for detecting defects in examination output images;
obtain at least one additional examination output image comprising a candidate defect;
apply the machine learning model to the at least one additional examination output image to thereby obtain machine learning output indicating whether the examination output images comprise one or more DOIs.

15. The computer system of claim 13 configured to operate, as part of a semiconductor fabrication process, an examination tool for examining one or more fabricated semiconductor specimens and generate the examination output images;
wherein the at least one processing circuitry is configured to generate the plurality of synthetic fault images by planting synthetic DOIs on-the-fly in the examination output images to thereby enable to use the plurality of synthetic fault images for real-time detection of DOIs in examination output images generated during the semiconductor fabrication process.

16. The computer system of claim 11, wherein the at least one processing circuitry is configured to augment the at least one synthetic DOI comprising: scaling the final DOI shape in one or two dimensions and/or applying rotation of the final DOI shape.

17. The computer system of claim 11, wherein the at least one processing circuitry is configured for fusing the primary DOI shape and secondary DOI shape to convolve the primary DOI shape with the secondary DOI shape.

18. The computer system of claim 11, wherein each shape in the collection of predefined secondary shapes is represented as a kernel having a certain size with pixels of different colors distributed within the kernel.

19. A non-transitory computer readable medium comprising instructions, that, when executed by a computer, cause the computer to perform a method of generating synthetic fault images of a semiconductor specimen, wherein a synthetic fault image comprises at least one synthetic defect of interest (DOI), the method comprising:
obtaining examination output images of a semiconductor specimen generated by an examination tool;
generating, from a plurality of examination output images, a respective plurality of synthetic fault images, comprising:
for each examination output image, determining at least one synthetic DOI, comprising:
determining a DOI planting location in the image;
determining a planting strength range;
determining a final DOI shape by fusing a primary DOI shape that is based on optical configuration of the examination tool and secondary DOI shape, selected from a collection of predefined secondary shapes, each comprising a plurality of pixels;
for each pixel in the final DOI shape, determining a respective DOI pixel strength based on a respective current pixel value and a planting strength selected from within the planting strength range; and
planting the synthetic DOI in the planting location in the image;
thereby generating a collection of synthetic fault images of the semiconductor specimen, wherein different synthetic fault images in the collection comprise different synthetic DOIs, which differentiate in one or more of planting location, DOI pixel strength, and final DOI shape.
